(19) United States
(12) Patent Application Publication
(10) Pub. No.: US 2017/0148990 A1
(43) Pub. Date: May 25, 2017

(54) MASK ASSEMBLY, METHOD OF MANUFACTURING MASK ASSEMBLY, AND METHOD OF MANUFACTURING DISPLAY APPARATUS

(71) Applicant: Samsung Display Co., Ltd., Yongin-si (KR)

(72) Inventor: Dongjin HA, Yongin-si (KR)

(21) Appl. No.: 15/179,822

(22) Filed: Jun. 10, 2016

(30) Foreign Application Priority Data
Nov. 20, 2015 (KR) 10-2015-0163346

(51) Int. Cl. H01L 51/00; B23K 1/00; B23K 9/007; H01L 51/56

(52) U.S. Cl. CPC H01L 51/0012; H01L 51/56; H01L 51/0029; B23K 1/0004; B23K 9/007; H01L 2227/323; H01L 2251/566

(57) ABSTRACT

A mask frame assembly including a frame including a first frame, a second frame, and a bonding layer disposed therebetween to couple the first frame to the second frame, a mask disposed on the frame, first and second ends of the mask overlapping the frame, and a welding unit penetrating the mask and the second frame to couple the mask to the second frame.

### CROSS-REFERENCE TO RELATED APPLICATION

This application claims priority from and the benefit of Korean Patent Application No. 10-2015-0163346, filed on Nov. 20, 2015, which is hereby incorporated by reference for all purposes as if fully set forth herein.

### BACKGROUND

### Field

Exemplary embodiments relate to a mask frame assembly, a method of manufacturing the mask frame assembly, and a method of manufacturing a display apparatus, and more particularly, to a mask frame assembly of which a frame is recyclable, a method of manufacturing the mask frame assembly, and a method of manufacturing a display apparatus.

### DISCUSSION OF THE BACKGROUND

In general, among flat displays, an organic light-emitting display apparatus may be an active emission-type display device, which has wide viewing angles and an excellent contrast ratio. An organic light-emitting display apparatus may be driven by a low voltage, and may be light and thin while having a high response rate. As such, organic light-emitting display apparatuses have drawn attention as next-generation display apparatuses.

Light-emitting devices may be divided into an inorganic light-emitting device and an organic light-emitting device, according to materials included in an emission layer. The organic light-emitting device may have better brightness, response rates, etc. than the inorganic light-emitting device, and may implement color display. As such, research for manufacturing an organic light-emitting device has been actively conducted.

An organic layer and/or an electrode of an organic light-emitting display apparatus may be manufactured by a vacuum deposition method. As the resolution of an organic light-emitting display apparatus increases, a width of an open slit of a mask used in the deposition process and a distribution of the open slits may be decreased.

The mask may be welded to a frame supporting the mask, and the mask may be formed as a mask frame assembly together with the frame, which may be utilized in the deposition process. The mask may have a stick shape, which may be formed in plural and coupled to one frame side by side, for manufacturing a large display panel.

In general, a mask of a mask frame assembly for a deposition process may be periodically replaced. As such, an expensive frame, to which the mask is coupled to via a welding unit, may also be replaced.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a mask frame assembly, and a method and apparatus for manufacturing a display apparatus by using the mask frame assembly, which may reduce the replacement of an expensive frame.

Additional aspects will be set forth in part in the description which follows and, in part, will be apparent from the disclosure, or may be learned by practice of the inventive concept.

An exemplary embodiments discloses a mask frame assembly including a frame including a first frame, a second frame, and a bonding layer disposed therebetween to couple the first frame to the second frame, a mask disposed on the frame, first and second ends of the mask overlapping the frame, and a welding unit penetrating the mask and the second frame to couple the mask to the second frame.

An exemplary embodiment also discloses a method of manufacturing a mask frame assembly including inserting a first frame, a second frame, and brazing powder disposed between the first frame and the second frame into a vacuum chamber, fusing the brazing powder by heating the vacuum chamber to about 900° C. or higher, cooling the brazing powder to form a bonding layer between the first frame and the second frame to couple the first frame to the second frame, disposing a mask on the second frame, first and second ends of the mask overlapping the second frame, and welding the mask and the second frame to form a welding unit.

An exemplary embodiment further discloses a method of manufacturing a display apparatus including inserting a mask frame assembly in a deposition chamber, arranging the mask frame assembly and a substrate relative to each other, and depositing a deposition material on the substrate by supplying the deposition material to the mask frame assembly from a deposition source, in which the mask frame assembly includes a frame including a first frame, a second frame, and a bonding layer disposed therebetween to couple the first frame to the second frame, a mask disposed on the frame, first and second ends of the mask overlapping the frame, and a welding unit penetrating the mask and the second frame to couple the mask to the second frame.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a perspective view of a mask frame assembly according to an exemplary embodiment.

FIG. 2 is a cross-sectional view of a side section of the mask frame assembly of FIG. 1.

FIG. 3 is a conceptual view of an apparatus for manufacturing a display apparatus by using the mask frame assembly of FIG. 1.

FIG. 4 is a plan view of a display apparatus manufactured by using the apparatus for manufacturing a display apparatus of FIG. 3.

FIG. 5 is a cross-sectional view taken along line V-V′ of the display apparatus of FIG. 4.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

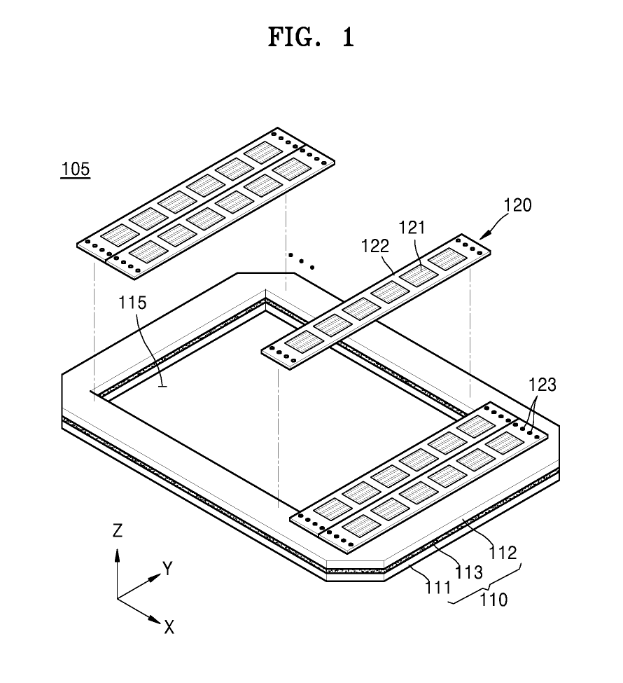

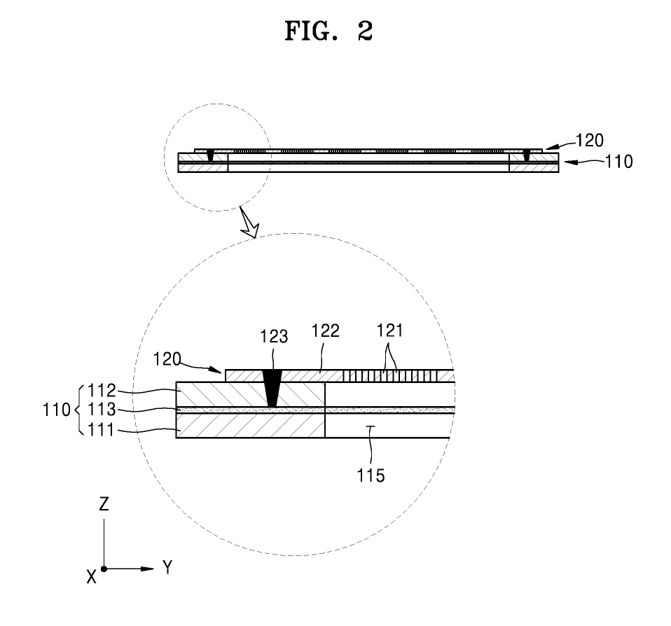

FIG. 1 is a perspective view of a mask frame assembly 105 according to an exemplary embodiment. FIG. 2 is a cross-sectional view of a side section of the mask frame assembly 105 of FIG. 1.

Referring to FIGS. 1 and 2, the mask frame assembly 105 may include a frame 110 and a mask 120. The frame 110 may include a first frame 111, a second frame 112, and a bonding layer 113 disposed therebetween for coupling the first frame 111 to the second frame 112.

The first frame 111 and the second frame 112 may have a frame shape. Each of the first frame 111 and the second frame 112 includes frames connected to each other. Alternatively, each of the first frame 111 and the second frame 112 may be formed from one plate. The first frame 111 and the second frame 112 may have central portions that are opened.

The frame 110 may have a quadrangular shape, in which an opening 115 having a hollow shape is formed at a center thereof. The mask 120 extending in a y-axis direction is coupled to the second frame 112. The frame 110 may have sufficient rigidity, and may include an elastic material. For example, the first frame 111 and the second frame 112 may include a material, such as an invar alloy or steel use stainless (SUS), which has sufficient rigidity and low thermal strain.

The bonding layer 113 for coupling the first frame 111 to the second frame 112 may be formed by a brazing process. More particularly, the bonding layer 113 may be a mixture of silver (Ag) in a range of about 70% to about 72%, copper (Cu) in a range of about 27% to about 29%, and nickel (Ni) in a range of about 0.5% to about 1%.

The brazing process for coupling the first frame 111 to the second frame 112 may include disposing brazing powder having substantially the same material property as the bonding layer 113 between the first frame 111 and the second frame 112. The first frame 111, the second frame 112, and the brazing powder are inserted into a vacuum chamber. An inner portion of the vacuum chamber may be heated to about 900° C. or higher, to fuse the brazing powder. The fused brazing powder, that is, the bonding layer 113, connects the first frame 111 and the second frame 112, and is discharged to the outside of the vacuum chamber and cooled, so that the first frame 111 and the second frame 112 are solidly coupled to each other.

The mask 120 may have a plate shape or a stick shape, and may be mounted on the frame 110. In this case, both ends of the mask 120 may be applied with tension and overlap the frame 110. As illustrated in FIG. 1, the mask 120 may be divided into stick-type masks. The mask 120 may include a main body 122 and a pattern hole 121, through which a deposition material penetrates.

The pattern hole 121 may have a hole shape penetrating the mask 120, and may extend in an x-axis direction, which is a width direction of the mask 120. Pattern holes 121 may be sequentially arranged in the y-axis direction, which is a length direction of the mask 120. The pattern holes 121 may form pattern units (not shown), which may be spaced apart from one another in the y-axis direction.

The mask 120 may be a magnetic thin film, and may include Ni or a Ni alloy. The mask 120 may include a nickel-cobalt alloy, on which a fine pattern may be easily formed thereon, and which has a desirable high level of surface roughness.

The mask 120 may be manufactured by an etching method. More particularly, the mask 120 may be manufactured by forming a photoresist layer having the same pattern as each pattern hole 121 on a thin plate by using a photoresist, or by etching a thin plate after attaching a film having the pattern of the pattern hole 121 on the thin plate. Alternatively, the mask 120 may be manufactured by an electro-forming method or an electro-less plating method.

The masks 120, which may be divided into multiple stick-shaped masks 120, may cover the entire opening 115 as illustrated in FIG. 1. Alternatively, the mask 120 may include one large member (not shown), such that one mask 120 may cover the entire opening 115 of the frame 110. Hereinafter, for convenience of description, the mask 120 will be described as having multiple stick-shaped masks.

Both ends of the mask 120 may be coupled to the second frame 112 via a welding unit 123 that penetrates the mask 120 and the second frame 112. More particularly, the mask 120 and the second frame 112 may be coupled to each other via an arc welding. By the arc welding, the mask 120 and a portion of the second frame 112 are fused to form one welding unit 123, and the mask 120 and the second frame 112 may be coupled to each other.

The mask frame assembly 105 according to the present exemplary embodiment may be used in a deposition process, which may be repeatedly utilized in a deposition chamber to deposit a deposition material on a panel of a display apparatus. When the deposition process is repeatedly performed, a deposition material may be solidified in the pattern hole 121 of the mask 120, which may not be discharged.

In a conventional mask frame assembly, a single frame and a mask may be coupled to each other via a welding unit. In this manner, the whole mask frame assembly may be replaced to discharge the solidified deposition material in a pattern hole of the conventional mask. More particularly, the welding unit may be removed to separate the mask from the frame, which may cause fracture or deformation in the frame.

According to an exemplary embodiment, the mask frame assembly 105 may include the first frame 111, the second frame 112, and the bonding layer 113 coupling the first frame 111 to the second frame 112, in which the mask 120 is coupled to the second frame 112 via the welding unit 123. In this manner, fracture or deformation on the first frame 111 may be prevented during the process of removing the mask 120, the second frame 112, and the bonding layer 113, as the first frame may not be connected to the mask 120. Accordingly, a new second frame 112 and a new bonding layer 113 may be disposed on the first frame 111. In this manner, a new mask frame assembly 105 may be manufactured by using the previously used first frame 111 without replacing the entire mask frame assembly 105.

According to an exemplary embodiment, as the first frame 111 may be continuously used, and the second frame 112 and the bonding layer 113 may be repeatedly replaced and disposed on the first frame 111, the first frame 111 may be used continuously in the deposition process. In this manner, costs for manufacturing the mask frame assembly 105 may be reduced.

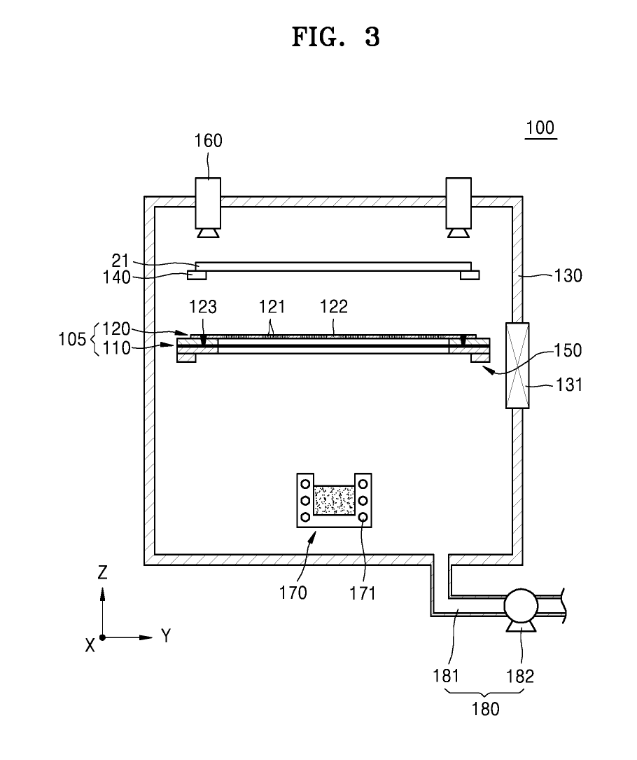

FIG. 3 is a conceptual view of an apparatus 100 for manufacturing a display apparatus by using the mask frame assembly 105 of FIG. 1.

Referring to FIG. 3, the apparatus 100 for manufacturing a display apparatus may include the mask frame assembly 105, a chamber 130, a first supporter 140, a second supporter 150, a vision unit 160, a deposition source 170, and an adsorption unit 180.

The mask frame assembly 105 may include the frame 110 and the mask 120. The mask 120 may be substantially the same as the mask 120 illustrated with reference to FIGS. 1 and 2, and thus, repeated description thereof will be omitted. The chamber 130 may include an inner space, and a portion of the chamber 130 may be open. A gate valve 131, etc. may be disposed in the open portion to open and close the open portion.

Hereinafter, an operation of the apparatus 100 for manufacturing a display apparatus will be described.

The gate valve 131 may be opened to open the chamber 130. Here, the adsorption unit 180 may adjust pressure of the chamber 130 similarly to air pressure. When the gate valve 131 is opened, a substrate 21 and the mask frame assembly 105 may be inserted into the chamber 130. The substrate 21 and the mask frame assembly 105 may be transported via a robot arm or a shuttle.

When the substrate 21 and the mask frame assembly 105 are inserted into the chamber 130, the gate valve 131 may operate to close the chamber 130, and the adsorption unit 180 may maintain the pressure of the chamber 130 substantially in a vacuum state. The deposition source 170 may evaporate or sublimate a deposition material, so that the deposition material is deposited on the substrate 21 via the mask frame assembly 105. The deposition material may be deposited on the substrate 21 according to a pattern of the pattern hole 121, by penetrating therethrough.

The first supporter 140 may support the substrate 21. The first supporter 140 may have various shapes. For example, the first supporter 140 may include a shuttle, an electrostatic chuck, etc., which may be arranged inside the chamber 130. Alternatively, the first supporter 140 may include an additional supporter frame arranged inside the chamber 130. Hereinafter, for convenience of description, the first supporter 140 will be described as to having the additional supporter frame.

The deposition material may be deposited on separate portions of the substrate 21. The pattern holes 121 may be formed in the mask 120 to be apart from each other. The substrate 21 may be separated into multiple parts after the deposition process is completed, such that multiple parts of the substrate 21 may be used to form multiple display apparatuses (not shown).

According to an exemplary embodiment, the deposition material may be alternatively deposited on the entire substrate 21. In this case, the pattern hole 121 may be formed on the entire surface of the mask 120. In particular, the substrate 21 may form one display apparatus (not shown) after the deposition is completed. Hereinafter, for convenience of description, the deposition material will be described as being disposed on separate portions of the substrate 21.

The second supporter 150 may be arranged between the first supporter 140 and the deposition source 170. The mask frame assembly 105 may be mounted on the second supporter 150. The second supporter 150 may align the mask frame assembly 105 and the substrate 21 by varying a displacement of the mask frame assembly 105 within a small range with respect to the substrate 21.

The vision unit 160 may include a camera. The vision unit 160 may photograph locations of the substrate 21 and the mask frame assembly 105, and provide data for aligning relative positions of the substrate 21 and the mask frame assembly 105.

The deposition source 170 may accommodate a deposition material. The deposition material may be a material that evaporates or sublimates, and may include at least one of an inorganic material, metal, and an organic material. Hereinafter, for convenience of description, the deposition material will be described as including an organic material.

The deposition source 170 may be arranged to face the frame 110. A portion of the deposition source 170 facing the frame 110 may be opened. The deposition source 170 may include a heater 171 for applying heat to the deposition material.

The adsorption unit 180 may be connected to the chamber 130, and may maintain a constant pressure in the chamber 130. The adsorption unit 180 may include a connection pipe 181 connected to the chamber 130, and a pump 182 mounted on the connection pipe 181.

According to an exemplary embodiment, the operation of the apparatus 100 for manufacturing a display apparatus illustrated with reference to FIG. 3 may be repeated, after removing the mask 120, the second frame 112, and the bonding layer 113 from the first frame 111, by polishing the mask 120, the second frame 112, and the bonding layer 113, after welding the mask 120 and the second frame 112.

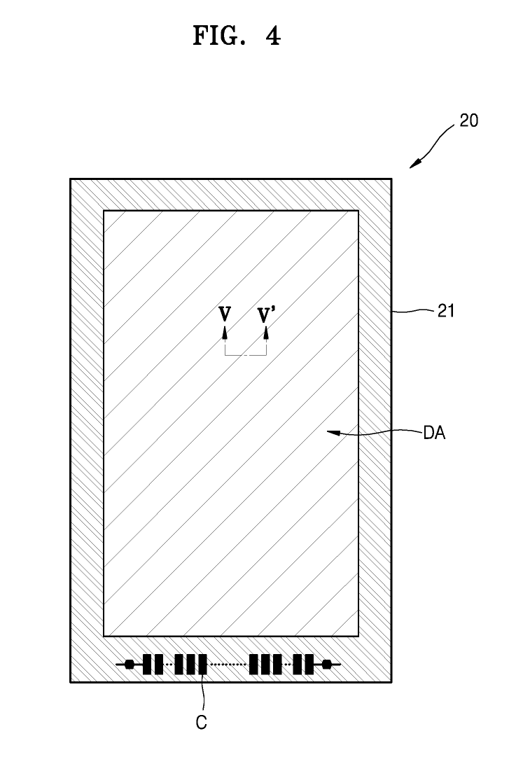

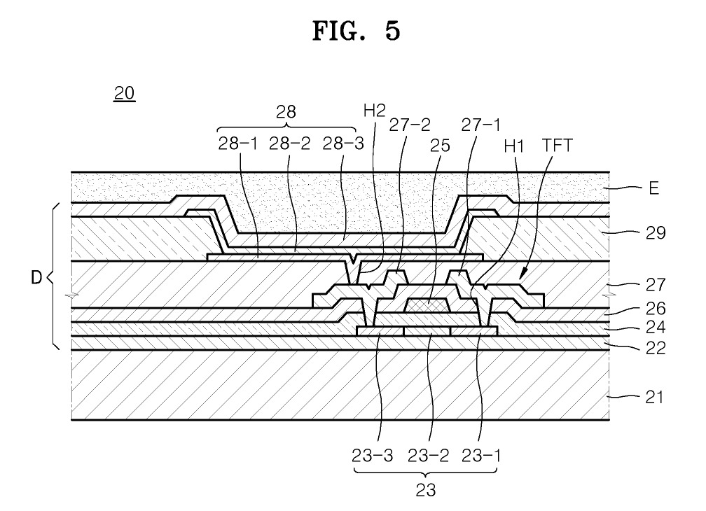

FIG. 4 is a plan view of a display apparatus 20 manufactured by using the apparatus 100 for manufacturing a display apparatus of FIG. 3. FIG. 5 is a cross-sectional view taken along line V-V′ of the display apparatus of FIG. 4.

Referring to FIGS. 4 and 5, the display apparatus 20 may include a substrate 21, on which a display area DA and a non-display area outside the display area DA are defined. An emission unit “D” may be disposed in the display area DA, and power wires (not shown), etc. may be disposed in the non-display area. A pad unit “C” may be disposed in the non-display area.

The display apparatus 20 may include the substrate 21 and the emission unit “D”. The display apparatus 20 may include a thin film encapsulation layer “E” formed above the emission unit “D”. The substrate 21 may include a plastic material, a metal material, such as SUS and Ti, and/or polyimide (PI). Hereinafter, for convenience of description, the substrate 21 will be described as including PI.

The emission unit “D” may be formed on the substrate 21. The emission unit D may include a thin-film transistor TFT, and a passivation layer 27 may be formed to cover the emission unit “D”. An organic light-emitting device (OLED) 28 may be formed on the passivation layer 27.

The substrate 21 may include a glass material. Alternatively, the substrate 21 may include a plastic material, a metal material, such as SUS and Ti, or polyimide (PI). Hereinafter, for convenience of description, the substrate 21 will be described as to including a glass material.

A buffer layer 22 including an organic compound and/or an inorganic compound is further formed on the substrate 21. The buffer layer 22 may include SiOₓ or SiNₓ. An active layer 23 is formed on the buffer layer 22 to have a predetermined pattern, the active layer 23 may be buried by a gate insulating layer 24. The active layer 23 may include a source area 23-1, a drain area 23-3, and a channel area 23-2 between the source area 23-1 and the drain area 23-3.

The active layer 23 may include various materials. For example, the active layer 23 may include an inorganic semiconductor material, such as amorphous silicon or crystalline silicon. As another example, the active layer 23 may include an oxide semiconductor. As another example, the active layer 23 may include an organic semiconductor material. Hereinafter, for convenience of description, the active layer 23 will be described as including amorphous silicon.

An amorphous silicon layer is formed on the buffer layer 22, and the amorphous silicon layer is crystallized to form a polycrystalline silicon layer. The polycrystalline silicon layer may then be patterned to form the active layer 23. The source area 23-1 and the drain area 23-3 of the active layer 23 may be doped with impurities depending on types of thin-film transistors, such as a driving thin-film transistor (not shown), a switching thin-film transistor (not shown), etc.

A gate electrode 25 corresponding to the active layer 23 and an interlayer insulating layer 26 covering the gate electrode 25 are formed on the gate insulating layer 24. A contact hole H1 is formed in the interlayer insulating layer 26 and the gate insulating layer 24, and a source electrode 27-1 and a drain electrode 27-2 are formed on the interlayer insulating layer 26, to contact the source area 23-1 and the drain area 23-3, respectively.

The passivation layer 27 is formed on the thin-film transistor TFT, and a pixel electrode 28-1 of the OLED 28 is formed on the passivation layer 27. The pixel electrode 28-1 contacts the drain electrode 27-2 of the thin-film transistor TFT through a via hole H2 formed in the passivation layer 27.

The passivation layer 27 may include a single layer or multiple layers including an inorganic material and/or an organic material. The passivation layer 27 may include a planarization layer to planarize a layer below the passivation layer 27. The passivation layer 27 may be curved in correspondence to a curved layer below the passivation layer 27. The passivation layer 27 may include a transparent insulator for a resonance effect.

The pixel electrode 28-1 is formed on the passivation layer 27, and a pixel-defining layer 29 including an organic material and/or an inorganic material may be disposed to cover the pixel electrode 28-1 and the passivation layer 27. An opening is formed in the pixel-defining layer 29 to expose the pixel electrode 28-1. The intermediate layer 28-2 and an opposite electrode 28-3 are formed at least on the pixel electrode 28-1.

The pixel electrode 28-1 may function as an anode, and the opposite electrode 28-3 may function as a cathode. Alternatively, the polarities of the pixel electrode 28-1 and the opposite electrode 28-3 may be the opposite. The pixel electrode 28-1 and the opposite electrode 28-3 are insulated from each other by the intermediate layer 28-2, and voltages of different polarities are applied to the intermediate layer 28-2, so that light is emitted from an organic emission layer.

The intermediate layer 28-2 may include the organic emission layer. Alternatively, the intermediate layer 28-2 may include the organic emission layer, and may further include at least one of a hole injection layer (HIL), a hole transport layer (HTL), an electron transport layer (ETL), and an electron injection layer (EIL). The intermediate layer 28-2 may include the organic emission layer, and may further include various other functional layers (not shown).

The intermediate layer 28-2 may be formed by using the apparatus 100 for manufacturing a display apparatus illustrated with reference to FIG. 3. A unit pixel (not shown) includes sub-pixels, which may emit various colors of light. For example, the sub-pixels may include sub-pixels R, G, and B which emit red, green, and blue colors of light, respectively, and sub-pixels (not shown) which may emit red, green, blue, and white colors of light, respectively.

The thin film encapsulation layer “E” may include inorganic layers or an inorganic layer and an organic layer. More particularly, the organic layer of the thin film encapsulation layer “E” may include a polymer, and may have a single layer or stacked layers including any one of polyethylene terephthalate, polyimide, polycarbonate, epoxy, polyethylene, and polyacrylate.

The organic layer may include polyacrylate. In detail, the organic layer may include a polymerized monomer composition including a diacrylate-based monomer and a triacrylate-based monomer. The monomer composition may further include a monoacrylate-based monomer and/or a general photo-initiator, such as TPO.

The inorganic layer of the thin film encapsulation layer “E” may include a single layer or stacked layers including a metal oxide or a metal nitride. More particularly, the inorganic layer may include any one of SiNₓ, Al₂O₃, SiO₂, and TiO₂. An uppermost layer of the thin film encapsulation layer “E”, which is exposed to the outside, may include an inorganic layer to prevent infiltration of moisture into the OLED 28.

The thin film encapsulation layer “E” may include at least one sandwich structure, in which at least one organic layer is disposed between at least two inorganic layers. As another example, the thin film encapsulation layer “E” may include at least one sandwich structure, in which at least one inorganic layer is disposed between at least two organic layers. As another example, the thin film encapsulation layer “E” may include at least one sandwich structure, in which at least one organic layer is disposed between at least two inorganic layers, and at least one sandwich structure, in which at least one inorganic layer is disposed between at least two organic layers.

The thin film encapsulation layer “E” may sequentially include a first inorganic layer, a first organic layer, and a second inorganic layer on the OLED 28. As another example, the thin film encapsulation layer “E” may sequentially include a first inorganic layer, a first organic layer, a second inorganic layer, a second organic layer, and a third inorganic layer on the OLED 28. As another example, the thin film encapsulation layer “E” may sequentially include a first inorganic layer, a first organic layer, a second inorganic layer, a second organic layer, a third inorganic layer, a third organic layer, and a fourth inorganic layer on the OLED 28.

A halogenated metal layer including lithium fluoride (LiF) may further be included between the OLED 28 and the first inorganic layer. The halogenated metal layer may prevent damage to the OLED 28 when the first inorganic layer is formed by sputtering. An area of the first organic layer may be smaller than an area of the second inorganic layer, and an area of the second organic layer may be smaller than an area of the third inorganic layer.

According to exemplary embodiments, a mask frame assembly includes a mask and a frame coupled to teach other, in which the mask may be replaceable, and the frame may be continuously used in a deposition process.

Although certain exemplary embodiments and implementations have been described herein, other embodiments and modifications will be apparent from this description. Accordingly, the inventive concept is not limited to such exemplary embodiments, but rather to the broader scope of the presented claims and various obvious modifications and equivalent arrangements.

What is claimed is:

1. A mask frame assembly, comprising:
a frame comprising a first frame, a second frame, and a bonding layer disposed therebetween to couple the first frame to the second frame;
a mask disposed on the frame, first and second ends of the mask overlapping the frame; and
a welding unit penetrating the mask and the second frame to couple the mask to the second frame.

2. The mask frame assembly of claim 1, wherein the first frame comprises an invar alloy.

3. The mask frame assembly of claim 1, wherein the second frame comprises an invar alloy.

4. The mask frame assembly of claim 1, wherein the bonding layer comprises silver (Ag) in a range of about 70% to about 72%, copper (Cu) in a range of about 27% to about 29%, and nickel (Ni) in a range of about 0.5% to about 1%.

5. A method of manufacturing a mask frame assembly, the method comprising:
inserting a first frame, a second frame, and brazing powder disposed between the first frame and the second frame into a vacuum chamber;
fusing the brazing powder by heating the vacuum chamber to about 900° C. or higher;
cooling the brazing powder to form a bonding layer between the first frame and the second frame to couple the first frame to the second frame;
disposing a mask on the second frame, first and second ends of the mask overlapping the second frame; and
welding the mask and the second frame to form a welding unit.

6. The method of claim 5, wherein the first frame comprises an invar alloy.

7. The method of claim 5, wherein the second frame comprises an invar alloy.

8. The method of claim 5, wherein the brazing powder comprises silver (Ag) in a range of about 70% to about 72%, copper (Cu) in a range of about 27% to about 29%, and nickel (Ni) in a range of about 0.5% to about 1%.

9. The method of claim 5, wherein the mask and the second frame are welded to each other via an arc welding.

10. The method of claim 5, further comprising removing a portion of the mask disposed outside the welding unit, after welding the mask and the second frame.

11. The method of claim 5, further comprising removing the mask, the second frame, and the bonding layer from the first frame, by polishing the mask, the second frame, and the bonding layer, after welding the mask and the second frame.

12. The method of claim 11, further comprising:
repeating the method of claim 5, after removing the mask, the second frame, and the bonding layer from the first frame and polishing the mask, the second frame, and the bonding layer.

13. A method of manufacturing a display apparatus, the method comprising:
inserting a mask frame assembly in a deposition chamber;
arranging the mask frame assembly and a substrate relative to each other; and
depositing a deposition material on the substrate by supplying the deposition material to the mask frame assembly from a deposition source,
wherein the mask frame assembly comprises:
a frame comprising a first frame, a second frame, and a bonding layer disposed therebetween to couple the first frame to the second frame;
a mask disposed on the frame, first and second ends of the mask overlapping the frame; and
a welding unit penetrating the mask and the second frame to couple the mask to the second frame.

14. The method of claim 13, wherein the first frame comprises an invar alloy.

15. The method claim 13, wherein the second frame comprises an invar alloy.

16. The method of claim 13, wherein the bonding layer comprises silver (Ag) in a range of about 70% to about 72%, copper (Cu) in a range of about 27% to about 29%, and nickel (Ni) in a range of about 0.5% to about 1%.

17. The method of claim 13, wherein the mask and the second frame are welded to each other via an arc welding.
